(19) United States
(12) Patent Application Publication
(10) Pub. No.: US 2016/0008850 A1
(43) Pub. Date: Jan. 14, 2016

(54) ULTRASONIC TRANSDUCER AND MANUFACTURING METHOD THEREFOR

(71) Applicant: ALPINION MEDICAL SYSTEMS CO., LTD., Hwaseong-si Gyeonggi-do (KR)

(72) Inventors: Jongkil KIM, Seoul (KR); Susung LEE, Yongin-si, (KR)

(21) Appl. No.: 14/771,179

(22) PCT Filed: Feb. 28, 2013
(86) PCT No.: PCT/KR2013/001672

§ 371 Date: Aug. 27, 2015

(30) Foreign Application Priority Data
Feb. 28, 2013 (KR) 10-2013-0022070

(51) Int. Cl. B06B 1/06; H01L 41/313; H01L 41/29; B06B 1/02; H01L 41/047

(52) U.S. Cl. CPC B06B 1/0644; B06B 1/0207; H01L 41/0475; H01L 41/29; H01L 41/313

(57) ABSTRACT

An ultrasonic transducer includes a piezoelectric layer for generating an ultrasonic by using a power received from outside, a ground electrode attached to a first surface of the piezoelectric layer, a signal electrode attached to a second surface of the piezoelectric layer, and circuit boards connected to the ground electrode and the signal electrode. A part of the ground electrode and a part of the signal electrode are directly connected to the circuit boards, each of the ground electrode and the signal electrode includes flexible material, and the circuit boards include rigid material. The circuit boards may be provided on both sides of the ground electrode and the signal electrode. This structure provides a direct connection of the ground electrode or the signal electrode and the circuit boards to improve issues of cost increase for manufacturing socket connector ultrasonic transducers socket volume increase, socket designing challenges and socket failures.

### TECHNICAL FIELD

The present disclosure, in some embodiments, relates to an ultrasonic transducer, and more particularly, to an ultrasonic transducer which improves issues with socket connector transducers, such as manufacturing cost increase, socket volume increase, socket designing challenges and socket failures.

### BACKGROUND

The statements in this section merely provide background information related to the present disclosure and do not necessarily constitute prior art.

An ultrasonic transducer is a device for transmitting an ultrasonic signal to a treatment region and receiving an ultrasonic echo signal reflected from the treatment region, to acquire an ultrasonic image of the treatment region.

The ultrasonic transducer is applicable to various industry fields. In particular, the ultrasonic transducer can be mainly used in the medical apparatus field such as an ultrasonic diagnosis apparatus that acquires a tomographic image of a soft tissue or an image of blood flow in a noninvasive manner by transmitting an ultrasonic signal from a body surface of a target object to a treatment region inside the body and receiving an echo signal reflected from the treatment region.

The principle of transmitting and receiving the ultrasonic by the transducer is to utilize the characteristics of a piezoelectric member. The piezoelectric member is material that converts electrical energy into mechanical energy and vice versa. For example, a piezoelectric member in an ultrasonic transducer is formed with top and bottom electrodes and is applied therethrough with electric power, when it serves to oscillate and interconvert an electrical signal and an acoustic signal.

FIGS. 1 and 2 are partial schematic diagrams of a typical ultrasonic transducer.

The ultrasonic transducer generally includes a body 100 for transmitting an ultrasonic wave or receiving an image signal that is back-reflected from the treatment region, an electrode assembly 130 connected to the body 100, and a circuit board 110 for processing power or image.

The electrode assembly 130 and the circuit board 110 are electrically connected to each other with a connection socket 120. However, the structure in which the electrode assembly 130 and the circuit board 110 are interconnected with the connection socket 120 causes a substantial cost increase in manufacturing the connection socket 120 and for attaching the connection socket 120 to the electrode assembly 130.

Further, with this structure, an ultrasonic transducer with a plurality of piezoelectric members installed needs to have a channel for the electrode assembly 130 to electrically connect to each of the piezoelectric members, and hence, more piezoelectric members installed lead to more voluminous socket and more complicated socket design.

In addition, the socket connection structure may cause a contact failure leading to an error in an electrical signal or an image signal.

### DISCLOSURE

### Technical Problem

Therefore, the present disclosure has been made in view of the above aspects, and it is an object of at least one embodiment of the present disclosure to provide an ultrasonic transducer which improves issues with socket connector transducers, such as manufacturing cost increase, socket volume increase, socket designing challenges and socket failures, and a method for manufacturing the ultrasonic transducer.

The technical problem to be solved by the present disclosure is not limited to the above-mentioned, and other technical problems addressed not mentioned herein can be clearly understood by one of ordinary skill in the pertinent art from the following descriptions.

### SUMMARY

According to some embodiments, an ultrasonic transducer includes a piezoelectric layer configured to generate an ultrasonic by using a power received from outside, a ground electrode configured to be attached to a first surface of the piezoelectric layer, a signal electrode configured to be attached to a second surface of the piezoelectric layer, and at least one circuit board configured to be connected to the ground electrode and the signal electrode. A part of the ground electrode and a part of the signal electrode are directly connected to the circuit board, each of the ground electrode and the signal electrode includes flexible material, and the circuit board includes rigid material.

According to another embodiment, an ultrasonic transducer includes a ground electrode configured to be grounded, a signal electrode configured to transfer a signal, a piezoelectric layer configured to be inserted between the ground electrode and the signal electrode, including piezoelectric material, and configured to generate an ultrasonic, at least one circuit board configured to insert each side of the ground electrode and the signal electrode therein, to be integrated with the ground electrode and the signal electrode, and a connector configured to be coupled with the circuit board and to electrically connect the circuit board with a body connecting unit installed between a main body of an ultrasonic diagnosis apparatus and the circuit board. Here, the ground electrode or the signal electrode includes a perforated portion where the piezoelectric layer is to be attached. The ground electrode or the signal electrode includes a plurality of signal channels electrically connected to the body connecting unit.

According to yet another embodiment, a method for manufacturing an ultrasonic transducer includes manufacturing a ground electrode and a signal electrode each including flexible material, attaching at least one circuit board laterally on both opposite sides of the ground electrode and the signal electrode, and fixedly inserting a piezoelectric layer between and centrally of the ground electrode and the signal electrode. The fixedly inserting of the piezoelectric layer includes forming a plurality of perforations on the ground electrode or the signal electrode where the piezoelectric layer is to be attached, and infusing an adhesive in the perforations.

### Advantageous Effects

According to the present disclosure as described above, an ultrasonic transducer and the method of manufacturing the ultrasonic transducer according to some embodiments provide a direct connection of a ground electrode or a signal electrode and a circuit board, and hence improves the issues with socket connector transducers, such as manufacturing cost increase, socket volume increase, socket designing challenges and socket failures.

### BRIEF DESCRIPTION OF DRAWINGS

FIGS. 1 and 2 are partial schematic diagrams of a typical ultrasonic transducer.

FIG. 3 is a partial perspective view of an ultrasonic transducer according to some embodiments of the present disclosure.

FIG. 4 is a side view of an ultrasonic transducer according to some embodiments of the present disclosure.

FIG. 5 is a flowchart of a method for manufacturing an ultrasonic transducer according to according to some embodiments of the present disclosure.

### REFERENCE NUMERALS

| | |
|---|---|
| 100: Body | 110: Circuit Board |
| 120: Connection Socket | 130: Electrode Assembly |
| 310: Piezoelectric Layer | 320: Ground Electrode |
| 321: Perforated Portion | 322: Perforation |
| 330: Signal Electrode | 340: Circuit Board |
| 341: Upper Board Portion | 342: Lower Board Portion |
| 343: Integrated Circuit | 410: Acoustic Lens |
| 420: Matching Layer | 430: Sound-absorbing Layer |
| 440: Body Coupler | 450: Connector |

### DETAILED DESCRIPTION

Hereinafter, at least one embodiment of the present disclosure will be described in detail with reference to the accompanying drawings. The present disclosure contemplates various changes and modifications to be made, although they are illustrated through some exemplary embodiments. The present disclosure should not be limited to these embodiments but various changes and modifications are made by one ordinarily skilled in the art within the subject matter, the idea and scope of the present disclosure as hereinafter claimed. In the following description, like reference numerals designate like elements, although the elements are shown in different drawings. In the accompanying drawings, structures are exaggerated to emphasize some embodiments of the disclosure or reduced to facilitate the comprehension thereof.

Terms such as first and second, which may be used to describe various components, should not be interpreted as limiting said components. The above terms are used only to distinguish one of the components from the others. For example, and without departing from the scope of the present disclosure, the first component can be designated as the second component, and vice versa. On the other hand, unless defined otherwise, all terms, including technical or scientific terms used herein have the same meaning as are generally understood by persons of skill in the art to which this disclosure pertains. The terms, such as those commonly used as in lexical definition, should be interpreted as having a meaning consistent with the meaning that has the context of the relevant art, and unless expressly defined in this application, they shall not be interpreted too ideally or impractically unless the present disclosure expressly defines them so.

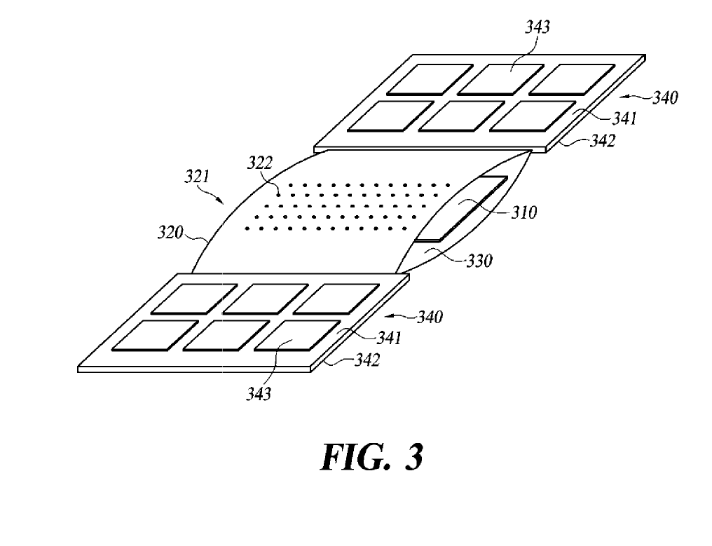

FIG. 3 is a partial perspective view of an ultrasonic transducer according to some embodiments of the present disclosure.

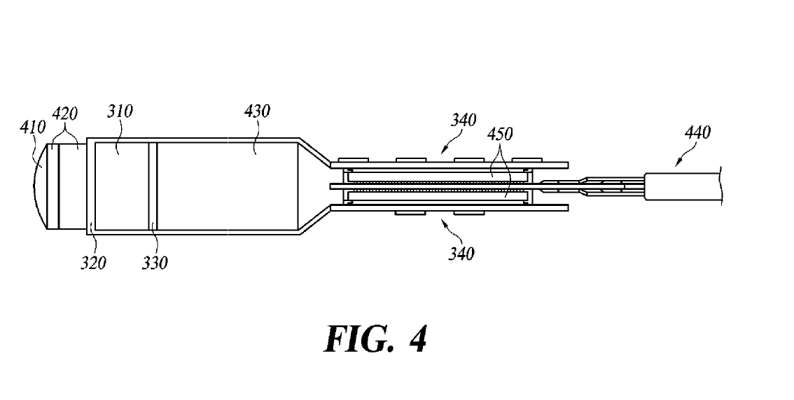

A piezoelectric layer 310 generates an ultrasonic by using a piezoelectric effect, and the ultrasonic generated by the piezoelectric layer 310 is emitted through an acoustic lens 410 (see FIG. 4). In some embodiments, the piezoelectric layer 310 has a single-layer structure, and in some embodiments, the piezoelectric layer 310 has a multilayer structure including a plurality of laminated piezoelectric layers 310.

A ground electrode 320 is attached to a first surface of the piezoelectric layer 310, and a signal electrode 330 is attached to a second surface of the piezoelectric layer 310. The signal electrode 330 is a pathway for inputting a power for generating the ultrasonic to the piezoelectric layer 310, and at the same time, it transfers an image signal on a treatment region, which is obtained from an ultrasonic back-reflected to the piezoelectric layer 310, to a main body (not shown) of an ultrasonic treatment apparatus.

The ground electrode 320 and the signal electrode 330 are integrations of channels respectively connected to a plurality of piezoelectric members included in the piezoelectric layer 310, and each of the channels is a pathway for transferring the power or the image signal.

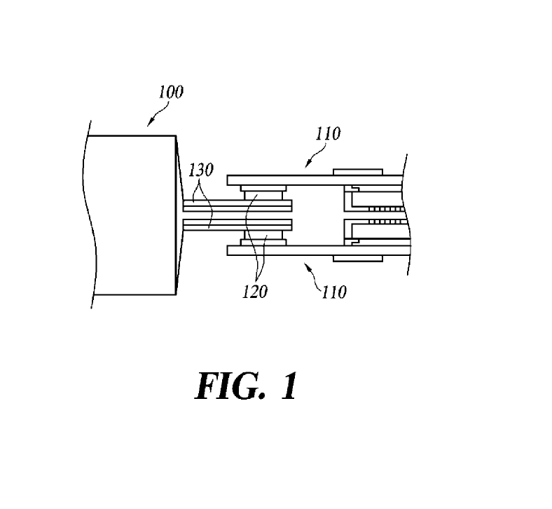

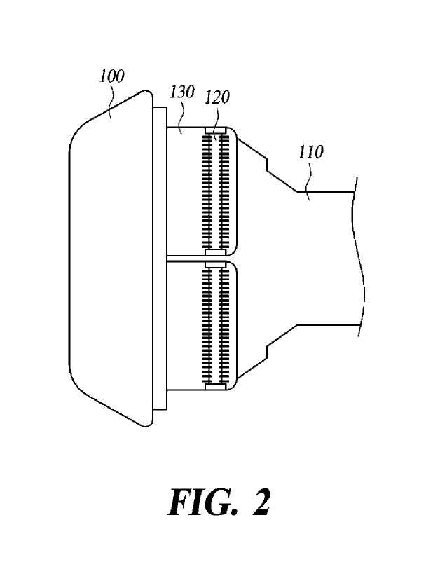

The ground electrode 320 and the signal electrode 330 are directly connected to at least one circuit board 340 with the above-mentioned structure, which eliminates the connection socket shown in FIGS. 1 and 2.

Various modes can be used for inserting the ground electrode 320 and the signal electrode 330 into the circuit board 340. In some embodiments, the ground electrode 320 and the signal electrode 330 are first laminated on a lower board portion 342, and an upper board portion 341 is subsequently laminated on top.

A process of integrating the circuit board 340, the ground electrode 320, and the signal electrode 330 in the above laminating manner is as follows.

In some embodiments, solidified resin films are respectively arranged between the lower board portion 342 and the signal electrode 330, between the upper board portion 341 and the ground electrode 320, and between the ground electrode 320 and the signal electrode 330, followed by heating and pressurizing the laminated structure of the lower board portion 342, the ground electrode 320, the signal electrode 330, and the upper board portion 341. Each of the resin films is then melted and works as an adhesive. Thereafter, the resin films are cured to firmly integrate the lower board portion 342, the ground electrode 320, the signal electrode 330, and the upper board portion 341, when the pressure is released to complete the process of attaching the laminated structure. In some embodiments, a liquid adhesive is applied by using a spray, a brush, or the like on a top surface of the lower board portion 342, one surface or both surfaces of the ground electrode 320 and the signal electrode 330, and a bottom surface of the upper board portion 341, and then a pressure is applied to the laminated structure. When the liquid adhesive is cured to firmly integrate the lower board portion 342, the ground electrode 320, the signal electrode 330, and the upper board portion 341, the pressure is released to complete the process of attaching the laminated structure. Attaching the laminated structure by using the liquid adhesive is advantageous over the case of using the resin film in that it dispenses with a separate heating device. On the other hand, the case of using the resin film is advantageous over using the liquid adhesive in that it dispenses with a separate process of applying the adhesive.

The circuit board 340 includes various integrated circuits 343 for processing a power and a signal, and hence it is formed with solid material. However, the ground electrode 320 and the signal electrode 330 are formed with flexible material. Therefore, the ground electrode 320 and the signal electrode 330 are coupled centrally with the solid piezoelectric layer 310 and laterally with the solid circuit board 340 to make the assembly rigid at the center and opposite side portions but flexibly bendable where the piezoelectric layer 310 and the circuit board 340 border each other.

In some embodiments, a method for coupling the piezoelectric layer 310 between the ground electrode 320 and the signal electrode 330 is as follows.

In some embodiments, the ground electrode 320 and a first surface of the piezoelectric layer 310 are arranged facing each other and the signal electrode 330 and a second surface of the piezoelectric layer 310 are arranged facing each other, and a perforated portion 321 including a plurality of perforations 322 is formed on each of the ground electrode 320 and the signal electrode 330. An electrically conductive adhesive is infused into each of the perforations 322, such that the infused electrically conductive adhesive couples the ground electrode 320 and the piezoelectric layer 310 and couples the signal electrode 330 and the piezoelectric layer 310. The plurality of perforations 322 is formed at portions of the ground electrode 320 and the signal electrode 330 in which the piezoelectric layer 310 is fixedly inserted, and the adhesive is infused into the perforations 322, thus attaching the piezoelectric layer 310 between the ground electrode 320 and the signal electrode 330.

The perforated portion 321 and the perforations 322 according to some embodiments are shown in FIG. 3. Each perforated portion 321 is formed in a manner that the plurality of perforations 322 is arranged at regular intervals in an X-axis direction and a Y-axis direction at the attachment sites of the ground electrode 320 and the piezoelectric layer 310 and at the attachment sites of the signal electrode 330 and the piezoelectric layer 310. The adhesive penetrates onto the surfaces of the piezoelectric layer 310 through each of the perforations 322, is dispersed around each of the perforations 322, where the piezoelectric layer 310 is coupled with the piezoelectric layer 310 and the signal electrode 330, respectively.

In the above-mentioned mode, the perforations 322 are formed at regular intervals, and the adhesive penetrates through each of the perforations 322, and hence the attachment sites of the ground electrode 320 and the signal electrode 330 with the piezoelectric layer 310 are evenly distributed over the piezoelectric layer 310, resulting in reduced faulty attachment and thus achieving a solid bonding.

In some embodiments, an electrically conductive adhesive is applied between the ground electrode 320 and a first surface of the piezoelectric layer 310 and between the signal electrode 330 and a second surface of the piezoelectric layer 310, and the piezoelectric layer 310 is attached between the ground electrode 320 and the signal electrode 330. The electrically conductive adhesive is used in portions of the ground electrode 320 and the signal electrode 330 in which the piezoelectric layer 310 is fixedly inserted, thus attaching the piezoelectric layer 310 between the ground electrode 320 and the signal electrode 330. Depending on the polarity of the piezoelectric layer 310, the ground electrode 320 and the signal electrode 330 can be arranged in an opposite manner.

In some embodiments, a combination of above-described two modes may be used for coupling the piezoelectric layer 310 between the ground electrode 320 and the signal electrode 330.

FIG. 4 is a side view of an ultrasonic transducer according to some embodiments of the present disclosure.

A matching layer 420 is arranged at a front end of the piezoelectric layer 310, and it serves to match an acoustic impedance of the piezoelectric layer 310 with that of a treatment region where the ultrasonic reaches. In some embodiments, the matching layer 420 includes a plurality of layers. The ultrasonic penetrated through the matching layer 420 passes through the acoustic lens 410, reflected at the treatment region, and then passes through the acoustic lens 410 and the matching layer 420, to return to the piezoelectric layer 310.

A sound-absorbing layer 430 suppresses a free oscillation of the piezoelectric layer 310, to reduce a pulse width of the ultrasonic, and blocks the ultrasonic from unnecessarily propagating in a backward direction of the piezoelectric layer 310, to prevent a distortion of an ultrasonic image.

The circuit board 340 processes a power received from a power source into a power for supplying to the piezoelectric layer 310 for generating an ultrasonic, or processes an image signal received from the piezoelectric layer 310 and transfers the image signal to a main body of an ultrasonic treatment apparatus.

Both opposite end portions of the ground electrode 320 and the signal electrode 330 respectively attached to the opposite surfaces of the piezoelectric layer 310 are inserted into the circuit board 340. A connector 450 is coupled with the circuit board 340 in which portions of the ground electrode 320 and the signal electrode 330 are inserted, and the connector 450 is coupled with a body coupler 440. Therefore, the power or the image signal is transferred between the piezoelectric layer 310 and the main body of the ultrasonic treatment apparatus via the signal electrode 330, the circuit board 340, the connector 450, and the body coupler 440.

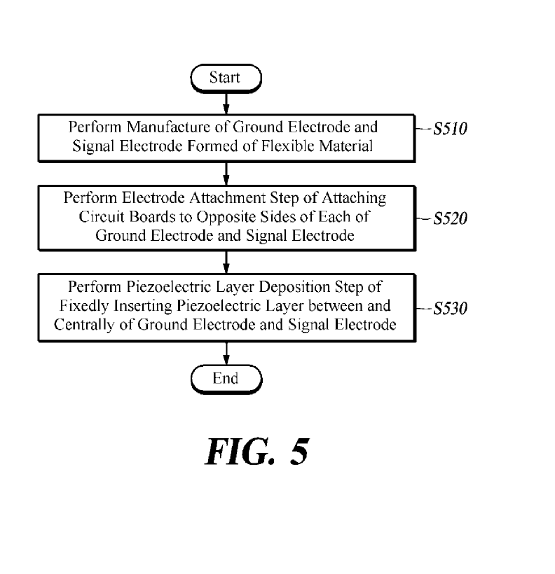

FIG. 5 is a flowchart of a method for manufacturing an ultrasonic transducer according to according to some embodiments of the present disclosure.

A method for manufacturing an ultrasonic transducer includes a first step of manufacturing a ground electrode and a signal electrode (step S510), a second step of respectively attaching circuit board laterally to both opposite sides of the ground electrode and the signal electrode (step S520), and a third step of inserting and attaching a piezoelectric layer between and centrally of the ground electrode and the signal electrode (step S530).

At the first step (step S510), the ground electrode and the signal electrode are manufactured with flexible material, and particularly, the signal electrode is formed with an integration of channels respectively connected to a plurality of piezoelectric members included in the piezoelectric layer.

At the second step (step S520), various modes can be used as the method for attaching the ground electrode and the signal electrode to the circuit board. In some embodiments, the ground electrode and the signal electrode are laminated on a lower board portion and then an upper board portion is laminated on the stack thereof. This second step enables the ground electrode and the signal electrode to be electrically connected to the circuit board without using a socket, and hence the manufacturing cost can be reduced compared to the connection structure using a socket, and the socket contact problem can be improved.

As described above, in some embodiments, the third step (step S530) includes a step of forming a plurality of perforations on a portion of the ground electrode or the signal electrode where the piezoelectric layer is fixedly inserted and a step of infusing an adhesive in the perforations. Further, in some embodiments, the third step includes a step of attaching the piezoelectric layer between the ground electrode and the signal electrode by using an electrically conductive adhesive on a portion of the ground electrode or the signal electrode where the piezoelectric layer is inserted and attached.

Although exemplary embodiments of the present disclosure have been described for illustrative purposes, those skilled in the art will appreciate that unless technically incompatible, they may be combined in various ways in order to implement other further embodiments.

### CROSS-REFERENCE TO RELATED APPLICATION

If applicable, this application claims priority under 35 U.S.C §119(a) of Patent Application No. 10-2013-0022070, filed on Feb. 28, 2013 in Korea, the entire content of which is incorporated herein by reference. In addition, this non-provisional application claims priority in countries, other than the U.S., with the same reason based on the Korean patent application, the entire content of which is hereby incorporated by reference.

1. An ultrasonic transducer, comprising:
a piezoelectric layer configured to generate an ultrasonic by using a power received from outside;
a ground electrode configured to be attached to a first surface of the piezoelectric layer;
a signal electrode configured to be attached to a second surface of the piezoelectric layer; and
at least one circuit board configured to be connected to the ground electrode and the signal electrode, wherein
a part of the ground electrode and a part of the signal electrode are directly connected to the circuit board,
each of the ground electrode and the signal electrode includes flexible material, and
the circuit board includes rigid material.

2. The ultrasonic transducer according to claim 1, wherein the circuit board is laterally provided on both opposite sides of the ground electrode and the signal electrode.

3. The ultrasonic transducer according to claim 1, wherein the piezoelectric layer includes a laminated structure of a plurality of boards each including piezoelectric material.

4. The ultrasonic transducer according to claim 1, wherein
the circuit board includes an upper board portion and a lower board portion on each of which an integrated circuit is mountable, and
the part of the ground electrode and the part of the signal electrode are inserted between the upper board portion and the lower board portion.

5. An ultrasonic transducer, comprising:
a ground electrode configured to be grounded;
a signal electrode configured to transfer a signal;
a piezoelectric layer configured to be inserted between the ground electrode and the signal electrode, including piezoelectric material, and configured to generate an ultrasonic;
at least one circuit board configured to insert each side of the ground electrode and the signal electrode therein, to be integrated with the ground electrode and the signal electrode; and
a connector configured to be coupled with the circuit board and to electrically connect the circuit board with a body connecting unit installed between a main body of an ultrasonic diagnosis apparatus and the circuit board, wherein
the ground electrode or the signal electrode includes a perforated portion where the piezoelectric layer is to be attached.

6. The ultrasonic transducer according to claim 5, wherein the perforated portion includes a plurality of perforations arranged along an X-axis direction and a Y-axis direction at regular intervals.

7. The ultrasonic transducer according to claim 5, wherein the ground electrode or the signal electrode includes a plurality of signal channels electrically connected to the body connecting unit.

8. A method for manufacturing an ultrasonic transducer, the method comprising:
manufacturing a ground electrode and a signal electrode each including flexible material;
attaching at least one circuit board laterally on both opposite sides of the ground electrode and the signal electrode; and
fixedly inserting a piezoelectric layer between and centrally of the ground electrode and the signal electrode.

9. The method according to claim 8, wherein the fixedly inserting of the piezoelectric layer includes:
forming a plurality of perforations on the ground electrode or the signal electrode where the piezoelectric layer is to be attached, and
infusing an adhesive in the perforations.

10. The method according to claim 8, wherein the fixedly inserting of the piezoelectric layer includes attaching the piezoelectric layer between the ground electrode and the signal electrode by applying a conductive adhesive on a portion of the ground electrode or the signal electrode where the piezoelectric layer is to be inserted and fixed.
